(19) United States
(12) Patent Application Publication
(10) Pub. No.: US 2004/0194002 A1
(43) Pub. Date: Sep. 30, 2004

(54) System and method for decoding noise-corrupted reed-solomon codes and communications terminal incorporating the same

(75) Inventor: Yumin Zhang, Allentown, PA (US)

Correspondence Address: HITT GAINES P.C., P.O. BOX 832570, RICHARDSON, TX, 75083, US

(73) Assignee: Lucent Technologies Inc., Murray Hill, NJ

(21) Appl. No.: 10/400,321

(22) Filed: Mar. 27, 2003

(51) Int. Cl. H03M 13/00

(52) U.S. Cl. 714/784

(57) ABSTRACT

A system and method for partially decoding a noise-corrupted Reed-Solomon (RS) code and a communications terminal incorporating the system or the method. In one embodiment, the system includes: (1) a syndrome sequence generator that computes a syndrome sequence Sₕ, S₁₊ₕ . . . S₂ₜ₋₁₊ₕ from the noise-corrupted RS code and (2) an error locator and magnitude polynomial generator that iteratively determines both the error locator polynomial and the error magnitude polynomial from the syndrome sequence.

### TECHNICAL FIELD OF THE INVENTION

The present invention is directed, in general, to communications and, more specifically, to a system and method for decoding noise-corrupted Reed-Solomon (RS) codes and a communications terminal incorporating the same.

### BACKGROUND OF THE INVENTION

The detection and correction of errors in wireless and wireline communications are vitally important. Those skilled in the communications art are familiar with RS codes, which can be used to detect and correct errors in the symbols that carry voice or video streams or data. RS codes find particularly advantageous use in radio-frequency (RF) communications, which are becoming evermore important in today's world.

RS codes are defined by the values of four parameters: the code length, the message length, the number of symbol errors that can be corrected and “h,” which relates to the roots of the polynomial used to generate the RS code. By far, the most common value for h is 1. Those skilled in the art refer to RS codes having an h of 1 as being “narrow-sense” RS codes.

However, as the use of RS codes has expanded, significant uses have arisen for RS codes having a value of h equal to 0 or greater than 1. RS codes having this range of h values have come to be called “non-narrow-sense” RS codes. One example of an application that uses for non-narrow-sense RS codes is the European standard called “Digital Video Broadcasting for Terrestrial Television,” or “DVB-T.”

Unfortunately, conventional algorithms for decoding RS codes are unsuitable for use with non-narrow-sense RS codes. Some algorithms do not provide adequate error correction. Others simply do not work. Accordingly, what is needed in the art is an algorithm that is effective for decoding non-narrow-sense RS codes. What is further needed in the art is a generalized algorithm suitable for decoding RS codes irrespective of whether they are narrow-sense or non-narrow-sense. What is still further needed in the art are systems and methods and communications terminals embodying the algorithm.

### SUMMARY OF THE INVENTION

To address the above-discussed deficiencies of the prior art, the present invention provides a system and method for partially decoding a noise-corrupted RS code and a communications terminal incorporating the system or the method. In one embodiment, the system includes: (1) a syndrome sequence generator that computes a syndrome sequence Sₕ, S₁₊ₕ . . . S₂ₜ₋₁₊ₕ from a noise-corrupted RS code and (2) an error locator and magnitude polynomial generator that iteratively determines both the error locator polynomial and the error magnitude polynomial from the syndrome sequence.

The present invention therefore provides a mechanism by which non-narrow-sense RS codes may be decoded efficiently, thereby allowing their widespread use in practical applications. In one embodiment of the present invention, h is 0 or greater than 1. Thus, the RS code is non-narrow-sense. However, in an alternative embodiment, h may assume any value equal to or greater than 0, allowing a single system to process both narrow-sense and non-narrow-sense RS codes.

In one embodiment of the present invention, the error locator and magnitude polynomial generator concurrently determines both the error locator polynomial and the error magnitude polynomial. Of course, the error locator and magnitude polynomial generator may determine these polynomials serially.

In one embodiment of the present invention, the error locator and magnitude polynomial generator employs a modified Berlekamp-Massey algorithm to determine both the error locator polynomial and the error magnitude polynomial. In a more specific embodiment, the error locator polynomial Λ(x) and the error magnitude polynomial Ω(x) satisfy the equation Λ(x)S(x)≡Ω(x) mod X^{2t+h}. S(x) is the syndrome equation formed using the sequence Sₕ, S₁₊ₕ . . . S₂ₜ₋₁₊ₕ.

In one embodiment of the present invention, the error locator and magnitude polynomial generator employs a modified Euclid's algorithm to determine both the error locator polynomial and the error magnitude polynomial. In a more specific embodiment, the error locator polynomial Λ(x) and the error magnitude polynomial Ω(x) satisfy the equation Λ(x)S(x)≡Ω(x) mod X^{2t+h}. Again, S(x) is the syndrome equation formed using the sequence Sₕ, S₁₊ₕ . . . S₂ₜ₋₁₊ₕ.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

For a more complete understanding of the present invention, reference is now made to the following descriptions taken in conjunction with the accompanying drawings, in which:

FIG. 1 illustrates a block diagram of one embodiment of a system for partially decoding an RS code constructed according to the principles of the present invention;

FIG. 2 illustrates a block diagram of one embodiment of a method of partially decoding an RS code carried out according to the principles of the present invention; and

FIG. 3 illustrates a block diagram of one embodiment of a communications terminal incorporating the system of FIG. 1 or the method of FIG. 2 and constructed according to the principles of the present invention.

### DETAILED DESCRIPTION

In 1958, I. S. Reed and G. Solomon made a significant contribution to burst-error-correction codes in a report titled “Polynomial Codes over Certain Finite Fields” at the MIT Lincoln Laboratory, in which they introduced RS codes. A thorough discussion of RS codes and decoding can be found in S. B. Wicker, Error Control Systems for Digital Communication and Storage, Prentice-Hall, 1995, I. S. Reed and X. Chen, Error-Control Coding for Data Networks, Kluwer Academic Publishers, 1999 and S. Lin and D. J. Costello, Jr., Error Control Coding: Fundamentals and Applications, Prentice-Hall, 1983, all of which are incorporated herein by reference.

Since that time, researchers around the world have come up with many different decoding algorithms for RS codes. The availability of fast, efficient decoding algorithms, together with the increasing power of modern digital signal processors (DSPs), have made RS codes one of the most popular burst-error-correction codes in modern communication systems during the past three decades.

Among the different RS decoding algorithms, two popular algorithms are the Berlekamp-Massey algorithm and Euclid's algorithm. The Berlekamp-Massey algorithm described in, inter alia, E. R. Berlekamp, “Nonbinary BCH Decoding,” International Symposium on Information Theory, San Remo, Italy, 1967 and J. L. Massey, “Shift Register Synthesis and BCH Encoding,” IEEE Transcripts on Information Theory, Vol. IT-15, No. 1, pp. 122-127, Jan. 1969 (both of which are incorporated herein by reference) was the first fast and efficient algorithm that uses a shift register-based approach to RS decoding, allowing the decoding of dozens of errors in some powerful RS codes. Another efficient iterative decoding algorithm is Euclid's algorithm, which was originally devised for finding the greatest common divisor of two integers. However, Euclid's algorithm can be extended to include more complex collections of algebraic objects, such as polynomials with coefficients in a finite field. Sugiyama, M. Kasahara, S. Hirasawa and T. Namekawa, “A Method for Solving Key Equation for Decoding Goppa Codes,” Information and Control, Vol. 27, pp. 87-99, 1975 (incorporated herein by reference) demonstrated that Euclid's algorithm can used to solve the key equation.

The above decoding algorithms are generally introduced only for narrow-sense RS codes. In practice, however, RS codes are not required to be narrow-sense. One example is the (255,239) RS code used in the Digital Video Broadcasting for Terrestrial Television (DVB-T) standard (Digital Video Broadcasting (DVB): Framing Structure, Channel Coding and Modulation for Digital Terrestrial Television (DVB-T), ETS 300 744, European Broadcasting Union, March 1997, incorporated herein by reference). The narrow-sense specific decoding algorithms cannot be applied directly to non-narrow-sense RS codes.

An (n,k) RS code capable of correcting t symbol errors has 2t consecutive power of α as roots for the generator polynomial g(x), where α is the primitive element of the Galois field. In other words, the following relation holds:

n−k=2t (1)

and the code generator polynomial is:

$$g ( x ) = {\prod }_{i = 0}^{2 t - 1} ( x - {α}^{+ i} ) h \geq 0 \qquad ( 2 )$$

As previously described, when h=1, the resulting RS code is called a narrow-sense code. In the DVB-T standard, h=0, which results in a non-narrow-sense code. Other choices of h are also possible and will yield the same error correction capability.

The decoding algorithms presented in S. B. Wicker, I. S. Reed, et al., and X. Chen, et al., supra, all assume h=1. Decoding normally follows the following steps:

Solve the key equation Λ(x)S(x)≡Ω(x) mod x^{2t+1} to get the error locator polynomial Λ(x) and the error magnitude polynomial Ω(x). (An alternative form of the key equation, Λ(x)(1+S(x))≡Ω(x) mod x^{2t+1} may be used, which gives the same decoding results.) Here, S(x) is the syndrome equation defined as S(x)=Σᵢ₌₀^{2t-1}Sᵢ₊ₕx^{i+h} and Sᵢ is the syndrome for αⁱ.

Use the Chien search (known to those skilled in the pertinent art) to find the roots of Λ(x) and thus the error positions.

Use the Forney algorithm (known to those skilled in the art) to find the roots of Ω(x) and thus the error magnitudes.

The narrow-sense specific algorithms cannot be applied directly to non-narrow-sense codes. For example, if Euclid's algorithm is used to decode the (255,239) non-narrow-sense RS code of the DVB-T standard, the decoder will be able to correct up to seven symbol errors instead of the designed eight symbol errors. Direct application of the Berlekamp-Massey algorithm on the DVB-T RS code simply fails. A significant modification to these algorithms is required to accommodate non-narrow-sense RS codes.

The most important modification is a new key equation for any choice of h (h≧0) (narrow-sense or non-narrow-sense). The new key equation given in accordance with the principles of the present invention is:

Λ(x)S(x)≡Ω(x) mod x^{2t+h} (3)

Given the new key equation, some modifications to the narrow-sense decoding algorithms are needed when calculating the error locator polynomial Λ(x) and the error magnitude polynomial Ω(x). Now, modified initial portions of the Berlekamp-Massey algorithm and Euclid's algorithm that accommodate both narrow-sense and non-narrow-sense RS codes will be presented. Once the initial portions have been executed, the error locator polynomial Λ(x) and the error magnitude polynomial Ω(x) will be obtained. Thereafter, the decoding process remains the same as that of narrow-sense RS codes.

### Modified Berlekamp-Massey Algorithm

The Berlekamp-Massey algorithm is well described in Wicker, supra, for the narrow-sense RS code case. To decode a non-narrow-sense code, the error locator polynomial Λ(x) is first found. The error magnitude polynomial is obtained by:

Ω(x)≡Λ(x)S(x) mod x^{2t+h}h≦0 (4)

For completeness, the modified Berlekamp-Massey algorithm, which is based on the algorithm given in Wicker, supra, is given below.

1. Compute the syndrome sequence Sₕ, S₁₊ₕ . . . S₂ₜ₋₁₊ₕ. Label them S₁, S₂ . . . S₂ₜ.

2. Set the initial values for the algorithm: k=0, Λ₍₀₎(x)=1, L=0, and T(x)=x.

3. Set k=k+1. Compute Δ^{(k)} using:

$${Δ}^{( k )} = {S}_{k} - {\sum }_{i = 1}^{L} {Λ}_{i}^{( k - 1 )} {S}_{k - i} \qquad ( 5 )$$

where Λᵢ^{(k-1)} is the coefficient for xⁱ in the polynomial Λ^{(k-1)}(x).

4. If Δ^{(k)}=0, then go to step 8.

5. Set Λ^{(k)}(x)=Λ^{(k-1)}(x)−Δ^{(k)}T(x).

6. If 2L≧k, then go to step 8.

7. Set L=k−L and T(x)=Λ^{(k-1)}(x)/Δ^{(k)}.

8. Set T(x)=x•T(x).

9. If k<2t, then go to step 3.

10. Λ(x)=Λ^{(2t)}(x) and Ω(x)=Λ(x) S(x) mod x^{2t+h}.

Once Λ(x) and Ω(x) are obtained, the conventional algorithm for narrow-sense RS codes is followed to complete the decoding of the RS code. Those skilled in the pertinent art understand the conventional algorithm for narrow-sense RS codes.

### Modified Euclid's Algorithm

The modified Euclid's algorithm for any h value (h≧0) is now given.

1. Compute the syndrome polynomial S(x).

2. Set the initial conditions: Q₋₁(x)=x^{2t+h}, Ω₀(x)=S(x), Λ₋₁(x)=0, Λ₀(x)=1.

3. Compute the successive remainder Ωᵢ(x) and the corresponding Λᵢ(x) using the following equations, until the stopping equation deg[Ωᵢ(x)≦t+h−1] is reached.

Ωᵢ=Ωᵢ₋₂−qᵢΩᵢ₋₁

Λᵢ=Λᵢ₋₂−qᵢΛᵢ₋₁

where deg[•] means the degree of the polynomial, and qᵢ

$$\frac{{Ω}_{i - 2} ( x )}{{Ω}_{i - 1} ( x )} .$$

4. Λ(x)=Λᵢ(x) and Ω(x)=Ωᵢ(x)

As with the Berlekamp-Massey algorithm, once Λ(x) and Ω(x) are obtained, the conventional algorithm for narrow-sense RS codes is followed to complete the decoding of the RS code.

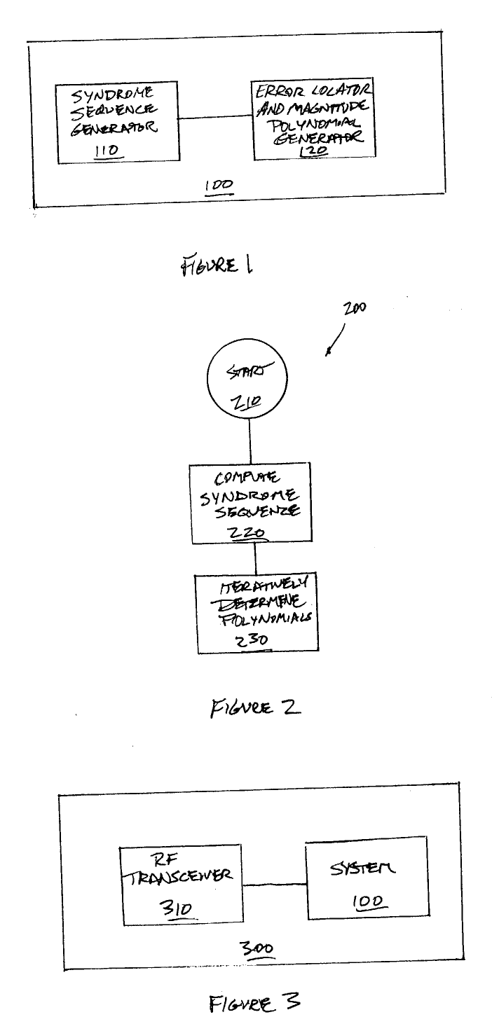

Referring initially to FIG. 1, illustrated is a block diagram of one embodiment of a system for partially decoding an RS code constructed according to the principles of the present invention.

The system, generally designated 100, is illustrated as including a syndrome sequence generator 110. The syndrome sequence generator computes a syndrome sequence Sₕ, S₁₊ₕ . . . S₂ₜ₋₁₊ₕ from the noise-corrupted RS code. Those skilled in the pertinent art understand that the syndrome sequence may be computed in accordance with the Berlekamp-Massey algorithm, Euclid's algorithm or another suitable conventional or later-discovered algorithm. The system 100 further includes an error locator and magnitude polynomial generator 120. The error locator and magnitude polynomial generator 120 iteratively determines both the error locator polynomial and the error magnitude polynomial from the syndrome sequence in accordance with the present invention.

With respect to the system 100, h may be 0 or greater than 1, in which case the system 100 is limited to processing only non-narrow-sense RS codes. Alternatively, h may assume any value equal to or greater than 0, allowing the system 100 to process both narrow-sense and non-narrow-sense RS codes.

Turning now to FIG. 2, illustrated is a block diagram of one embodiment of a method of partially decoding an RS code carried out according to the principles of the present invention.

The method, generally designated 200, begins with a start step 210. In a step 220, a syndrome sequence S for Sₕ, S₁₊ₕ . . . S₂ₜ₋₁₊ₕ is computed from the noise-corrupted RS code. In a step 230, both the error locator polynomial and the error magnitude polynomial is iteratively determined from the syndrome sequence in accordance with the present invention.

Turning now to FIG. 3, illustrated is a block diagram of one embodiment of a communications terminal incorporating the system of FIG. 1 or the method of FIG. 2 and constructed according to the principles of the present invention.

The communications terminal, generally designated 300, is illustrated as including an RF transceiver 310. The RF transceiver is responsible for transmitting and receiving symbols embodying user data and corresponding noise-corrupted RS codes. The RS codes need to be decoded to determine whether or not errors are present in the symbols embodying the user data and, if so, where those errors are present. Further, if the number of errors is within the capability of the RS code to correct, the RS codes can allow the errors in the user data to be corrected.

Accordingly, the communications terminal 300 is further illustrated as including a system 100 for partially decoding the RS codes. The system 100 is as it has been described above in conjunction with FIG. 1.

In one embodiment of the present invention, the system 100 is embodied in digital logic, including one or more shift registers and combinatorial logic (not shown) suitable for carrying out one of the above-described decoding algorithms. In a more specific embodiment, a DSP can be adapted to perform the needed processing.

The speed of the digital logic is preferably such that decoding can occur in real-time as symbols and associated RS codes are received. Errors can therefore be corrected “on-the-fly,” and excessive errors (exceeding the capability of the RS code to correct) can trigger a request on the part of the transceiver to a distant terminal for the symbols adversely affected by the excessive errors to be retransmitted.

Although the present invention has been described in detail, those skilled in the art should understand that they can make various changes, substitutions and alterations herein without departing from the spirit and scope of the invention in its broadest form.

What is claimed is:

1. A system for partially decoding a noise-corrupted Reed-Solomon code, comprising:
a syndrome sequence generator that computes a syndrome sequence Sₕ, S₁₊ₕ . . . S₂ₜ₋₁₊ₕ from said noise-corrupted Reed-Solomon code; and
an error locator and magnitude polynomial generator that iteratively determines both said error locator polynomial and said error magnitude polynomial from said syndrome sequence.

2. The system as recited in claim 1 wherein said h is 0 or greater than 1.

3. The system as recited in claim 1 wherein said error locator and magnitude polynomial generator concurrently determines both said error locator polynomial and said error magnitude polynomial using a modified Euclid's algorithm.

4. The system as recited in claim 3 wherein said error locator polynomial Λ(x) and said error magnitude polynomial Ω(x) satisfy Λ(x) S(x)≡Ω(x) mod x^{2t+h}.

5. The system as recited in claim 1 wherein said error locator and magnitude polynomial generator employs a modified Berlekamp-Massey algorithm to determine both said error locator polynomial and said error magnitude polynomial in separate steps.

6. The system as recited in claim 5 wherein said error locator polynomial Λ(x) and said error magnitude polynomial Ω(x) satisfy Λ(x) S(x)≡Ω(x) mod x^{2t+h}.

7. A method of partially decoding a noise-corrupted Reed-Solomon code, comprising:
computing a syndrome sequence Sₕ, S₁₊ₕ . . . S₂ₜ₋₁₊ₕ from said noise-corrupted Reed-Solomon code; and
iteratively determining both said error locator polynomial and said error magnitude polynomial from said syndrome sequence.

8. The method as recited in claim 7 wherein said h is 0 or greater than 1.

9. The method as recited in claim 7 wherein said iteratively determining comprises concurrently determining both said error locator polynomial and said error magnitude polynomial using a modified Euclid's algorithm.

10. The method as recited in claim 9 wherein said error locator polynomial Λ(x) and said error magnitude polynomial Ω(x) satisfy Λ(x) S(x)≡Ω(x) mod x^{2t+h}.

11. The method as recited in claim 7 wherein said error locator and magnitude polynomial generator employs a modified Berlekamp-Massey algorithm to determine both said error locator polynomial and said error magnitude polynomial in separate steps.

12. The method as recited in claim 11 wherein said error locator polynomial Λ(x) and said error magnitude polynomial Ω(x) satisfy Λ(x) S(x)=Ω(x) mod x^{st+h}.

13. A communications terminal, comprising:
a radio frequency transceiver for receiving symbols embodying user data and a corresponding noise-corrupted Reed-Solomon code; and
a system, coupled to said transceiver, for partially decoding said noise-corrupted Reed-Solomon code, including:
a syndrome sequence generator that computes a syndrome sequence Sₕ, S₁₊ₕ . . . S₂ₜ₋₁₊ₕ from said noise-corrupted Reed-Solomon code, and
an error locator and magnitude polynomial generator that iteratively determines both said error locator polynomial and said error magnitude polynomial from said syndrome sequence.

14. The communications terminal as recited in claim 13 wherein said h is 0 or greater than 1.

15. The communications terminal as recited in claim 13 wherein said error locator and magnitude polynomial generator concurrently determines both said error locator polynomial and said error magnitude polynomial using a modified Euclid's algorithm.

16. The communications terminal as recited in claim 15 wherein said error locator polynomial Λ(x) and said error magnitude polynomial Ω(x) satisfy Λ(x) S(x)≡Ω(x) mod x^{2t+h}.

17. The communications terminal as recited in claim 13 wherein said error locator and magnitude polynomial generator employs a modified Berlekamp-Massey algorithm to determine both said error locator polynomial and said error magnitude polynomial in separate steps.

18. The communications terminal as recited in claim 17 wherein said error locator polynomial Λ(x) and said error magnitude polynomial Ω(x) satisfy Λ(x) S(x)≡Ω(x) mod x^{2t+h}.
